(19) United States
(12) Patent Application Publication
(10) Pub. No.: US 2023/0040743 A1
(43) Pub. Date: Feb. 9, 2023

(54) METHOD AND SYSTEM FOR DYNAMIC VOICE ENHANCEMENT

(71) Applicant: HARMAN INTERNATIONAL INDUSTRIES, INCORPORATED, Stamford, CT (US)

(72) Inventors: Shao-Fu SHIH, Mountain View, CA (US); Jianwen ZHENG, Shenzhen (CN); Yi XIAO, Shenzhen (CN); Evin JIAO, ShenZhen City (CN)

(73) Assignee: HARMAN INTERNATIONAL INDUSTRIES, INCORPORATED, Stamford, CT (US)

(21) Appl. No.: 17/879,561

(22) Filed: Aug. 2, 2022

(30) Foreign Application Priority Data
Aug. 5, 2021 (CN) 202110895493.X

(51) Int. Cl. G10L 21/034; G10L 25/78; H04S 3/00; H04S 1/00

(52) U.S. Cl. CPC G10L 21/034; G10L 25/78; H04S 3/008; H04S 1/007; H04S 2400/01; H04S 2400/05; H04S 2400/13

(57) ABSTRACT

The present disclosure provides a method and system for voice enhancement. The method and system of the present disclosure may simultaneously perform signal processing of two paths on an input signal. The first path signal processing includes receiving an audio source input and performing dynamic loudness balancing on the audio source input based on a first gain control parameter. The second path signal processing includes: performing voice detection on the audio source input and calculating a detection confidence; and calculating a second gain control parameter based on the detection confidence. The first path signal processing and the second path signal processing may be synchronous or asynchronous. The method of the present disclosure also includes updating the first gain control parameter with the second gain control parameter calculated by a second processing path and performing the first path signal processing based on the updated first gain control parameter.

### CROSS-REFERENCE TO RELATED APPLICATIONS

This application claims priority to Chinese application Serial No. 202110895493.X filed Aug. 5, 2021, the disclosure of which is hereby incorporated in its entirety by reference herein.

### TECHNICAL FIELD

The present disclosure relates generally to the field of audio signal processing, and more particularly, to a method and system for dynamic voice enhancement of an audio source.

### BACKGROUND

Thanks to new ways of media consumption such as high-definition cable TV and online streaming, and with the advent of large-screen TVs and displays, the cinema experience is gaining popularity in the consumer market. These media sources are often accompanied by multi-channel audio technology or commonly referred to as surround technology. Surround providers such as Dolby, THX, and DTS have their own multi-channel audio encoding technology that provides a better spatial audio resolution for source content. Since one purpose of content in a movie format is to provide an immersive surround experience, it is often preferred to sacrifice voice intelligibility in favor of the surround experience. While this provides benefits in terms of immersion and spatial resolution, it often results in poor voice quality and sometimes even difficulty in understanding the movie content. In order to improve the quality of voice in a movie content source to improve intelligibility and audibility, methods of voice enhancement are often applied to the movie content.

A common method for existing voice enhancement is to utilize static equalization. This method applies static equalization only on an audio channel about 200 Hz to 4 kHz to increase the loudness of a voice band. This implementation requires very few system resources, but the distortion that occurs in this method is obvious. Since this implementation method works all the time even when there is no voice or dialogue in a clip, a pitch imbalance will be caused, and the background will be amplified. A more advanced method is to first detect voice within each time frame, and then automatically process an audio signal based on the detection result. This one-way execution method requires accurate detection of voice and fast response of system processing. However, some existing methods cannot detect voice quickly and accurately, and often color a signal so that it sounds harsh.

Therefore, there is a need for an improved technical solution to overcome the above-mentioned shortcomings in the existing solutions.

### SUMMARY

According to an aspect of the present disclosure, a method of dynamic voice enhancement is provided. The method may include performing a first path signal processing, the first path signal processing including receiving an audio source input and performing dynamic loudness balancing on the audio source input based on a first gain control parameter. The method may also include: performing a second path signal processing, the second path signal processing including performing voice detection on the audio source input and calculating a detection confidence, wherein the detection confidence indicates the possibility of voice in the audio source input; and calculating a second gain control parameter based on the detection confidence. The method may further include updating the first gain control parameter with the second gain control parameter, and performing the first path signal processing based on the updated first gain control parameter.

According to one or more embodiments, the audio source input may include a multi-channel source input, and performing voice detection on the audio source input and calculating a detection confidence may include: extracting a center channel signal from the multi-channel source input; performing normalization on the center channel signal; and performing fast autocorrelation on the normalized center channel signal, the result of the fast autocorrelation representing the detection confidence.

According to one or more embodiments, calculating a second gain control parameter based on the detection confidence may include: calculating the second gain control parameter based on a logarithmic function of the detection confidence; smoothing the calculated second gain control parameter; and limiting the smoothed second gain control parameter.

According to one or more embodiments, the audio source input may include a multi-channel source input, and performing dynamic loudness balancing on the audio source input includes: extracting a center channel signal from the multi-channel source input; enhancing the loudness of the center channel signal and reducing the loudness of other channel signals based on the first gain control parameter or the updated first gain control parameter; and concatenating and mixing the enhanced center channel signal and the reduced other channel signals to generate an output signal.

According to one or more embodiments, the method may also include performing crossover filtering on the audio source input before performing the dynamic loudness balancing.

According to one or more embodiments, the method may also include: performing the dynamic loudness balancing only on signals in a mid frequency range of the audio source input; and concatenating and mixing signals in a low frequency range and a high frequency range of the audio source input and signals in the mid frequency range of the audio source input after the dynamic loudness balancing to generate the output signal.

According to one or more embodiments, the audio source input also includes a dual-channel source input, and the method also includes generating a multi-channel source input based on the dual-channel source input.

According to one or more embodiments, the generating a multi-channel source input based on the dual-channel source input may include: performing a cross-correlation between a left channel signal and a right channel signal from the dual-channel source input; and generating the multi-channel source input according to a combination ratio. The combination ratio depends on the result of the cross-correlation.

According to one or more embodiments, the first path signal processing and the second path signal processing are synchronous or asynchronous.

According to another aspect of the present disclosure, a system for voice enhancement is provided, including: a memory and a processor. The memory is configured to store computer-executable instructions. The processor is configured to execute the instructions to implement the method described above.

### BRIEF DESCRIPTION OF THE DRAWINGS

The present disclosure may be better understood by reading the following description of non-limiting implementations with reference to the accompanying drawings, in which:

FIG. 1 schematically shows a schematic block diagram of voice enhancement according to one or more embodiments of an implementation of the present disclosure;

FIG. 2 exemplarily shows a schematic block diagram of voice detection according to one or more embodiments of the present disclosure;

FIG. 3 exemplarily shows a schematic block diagram of gain estimation based on voice detection according to one or more embodiments of the present disclosure;

FIG. 4 exemplarily shows a schematic diagram of a dynamic loudness balancing process according to one or more embodiments of the present disclosure;

FIG. 5 shows a schematic diagram of voice enhancement according to one or more embodiments of another implementation of the present disclosure;

FIG. 6 shows a schematic diagram of a dynamic loudness balancing process according to one or more embodiments of the implementation in FIG. 5;

FIG. 7 schematically shows a process of generating a multi-channel source input based on a dual-channel source input in the case where a source input is the dual-channel source input, according to one or more embodiments of the present disclosure; and

FIG. 8 schematically shows a method for dynamic voice enhancement according to one or more embodiments of the present disclosure.

### DETAILED DESCRIPTION

It should be understood that the following description of the embodiments is given for purposes of illustration only and not limitation. The division of examples in functional blocks, modules or units shown in the figures should not be construed as implying that these functional blocks, modules or units must be implemented as physically separate units. The functional blocks, modules or units shown or described may be implemented as separate units, circuits, chips, functional blocks, modules, or circuit elements. One or more functional blocks or units may also be implemented in a common circuit, chip, circuit element, or unit.

The use of singular terms (for example, but not limited to, “a”) is not intended to limit the number of items. Relational terms, for example but not limited to, “top,” “bottom,” “left,” “right,” “upper,” “lower,” “down,” “up,” “side,” “first,” “second” (“third,” etc.), “entry,” “exit,” etc., are used herein for clarity in specific reference to the drawings and are not intended to limit the scope of the present disclosure or the appended claims, unless otherwise noted. The terms “couple,” “coupling,” “being coupled,” “coupled,” “coupler,” and similar terms are used broadly herein and may include any method or device for fixing, bonding, adhering, fastening, attaching, associating, inserting, forming thereon or therein, communicating with, or otherwise directly or indirectly mechanically, magnetically, electrically, chemically, and operatively associated with an intermediate element and one or more members, or may also include, but is not limited to, one member being integrally formed with another member in a unified manner. Coupling may occur in any direction, including rotationally. The terms “including” and “such as” are illustrative rather than restrictive, and the word “may” entails “may, but not necessarily,” unless stated otherwise. Although any other language is used in the present disclosure, the embodiments shown in the figures are examples given for purposes of illustration and explanation and are not the only embodiments of the subject matter herein.

In order to overcome the defects of the existing technical solutions and improve the quality of voice output so as to bring a better experience to users, the present disclosure proposes a solution of actively detecting human voice and dynamically enhancing voice loudness in an audio source (for example, a theater audio source) based on a detection confidence that indicates the possibility of voice in an audio source input. The method and system of the present disclosure may simultaneously perform signal processing of two paths on an input signal. The first path signal processing includes receiving an audio source input and performing dynamic loudness balancing on the audio source input based on a first gain control parameter. The second path signal processing includes: performing voice detection on the audio source input and calculating a detection confidence; and calculating a second gain control parameter based on the detection confidence. The first path signal processing and the second path signal processing may be synchronous or asynchronous. The method of the present disclosure also includes updating the first gain control parameter with the second gain control parameter calculated by a second processing path, and performing the first path signal processing based on the updated first gain control parameter. The method and system of the present disclosure can better enhance the intelligibility of voice and improve the user's experience of using audio products.

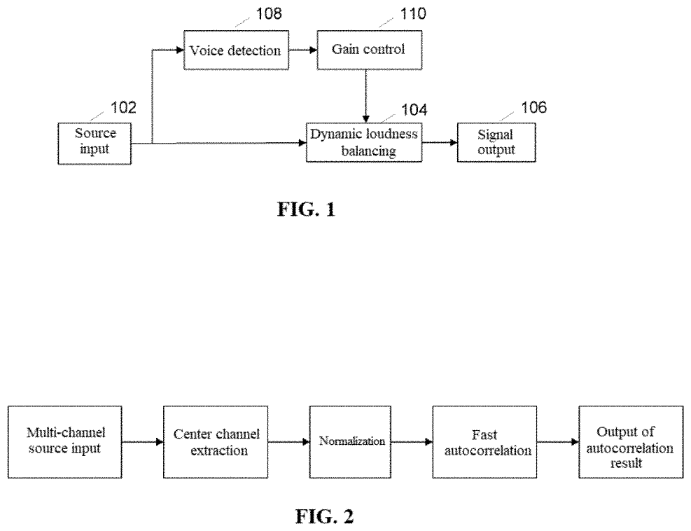

The method and system of dynamic voice enhancement according to various embodiments of various implementations of the present disclosure will be described in detail below with reference to the accompanying drawings. FIG. 1 shows a schematic block diagram of a voice method and system according to one or more embodiments of an implementation of the present disclosure. For ease of understanding, the present disclosure will be described with reference to several modules according to main processing procedures of the method and system. It will be appreciated by those skilled in the art that the reference to the description is for the purpose of describing the solution more clearly, but not for the purpose of limitation.

FIG. 1 shows a schematic diagram according to one or more embodiments of an implementation of the present disclosure. In one or more embodiments shown in FIG. 1, the method and system of processing audio source input signals in the present disclosure include a source input module 102, a dynamic loudness balancing module 104, a signal output module 106, a voice detection module 108, and a gain control module 110. As can be seen from FIG. 1, the method and system of the present disclosure may simultaneously perform signal processing of two paths on an input signal. The first path signal processing is mainly used to perform dynamic loudness balancing on a received source input signal. The second path signal processing is used to perform voice detection on the received source input signal and estimate a gain. The first path signal processing and the second path signal processing may be performed synchronously or asynchronously. This depends on the processing power and latency requirements of an actual system. This dual-path processing design for source input signals minimizes the delay and prevents audio distortion. For example, when the first path signal processing and the second signal processing are performed asynchronously, on the one hand, a signal may pass through the entire system quickly and with low delay; on the other hand, a gain may be estimated at a relatively low rate, so that the estimated gain has a higher accuracy and smoothness, which is a huge help in preventing audio distortion.

Referring to FIG. 1, for example, the first path signal processing may include: receiving an audio source input signal through the source input module 102 and performing a dynamic balancing on the received audio source input signal based on a current gain control parameter through the dynamic loudness balancing module 104. The second path processing may include: detecting the audio source input signal received from the input module 102 at the voice detection module 108 and calculating a detection confidence. For example, the second path processing also includes the gain control module 110 may estimate a new gain control parameter based on the calculated detection confidence.

The new gain control parameter estimated by the gain control module 110 may be used to update the gain control parameter currently used by the dynamic loudness balancing module 104. Thus, the dynamic loudness balancing module 104 may perform the first path signal processing based on the updated gain control parameter. That is, the dynamic loudness balancing module 104 may perform dynamic loudness balancing on the received audio source input signal based on the updated gain control parameter. The audio signal after the dynamic loudness balancing may be output through the signal output module 106.

The audio source input may include a multi-channel source input, a dual-channel source input, and a single-channel source input. The processing aspects of different source inputs will be described below respectively with reference to the accompanying drawings. FIG. 2 exemplarily shows a schematic block diagram of voice detection according to one or more embodiments of the present disclosure, where the audio input source includes a multi-channel source input. The voice detection process shown in FIG. 2 may be performed, for example, by the voice detection module 108 in FIG. 1. As shown in FIG. 2, center channel extraction is performed first, that is, center channel signals are extracted from the multi-channel source input. Usually, most of voice signals exist in a center channel. Then, normalization is performed on the extracted center channel signals so that the input signal is scaled to a similar level. The normalized signal is, for example, represented by the following equation:

x_{i_norm}(n)=(xᵢ(n)−μᵢ)/σᵢ (1)

where xᵢ(n) represents an input signal at an n^{th} sampling point of an ith time frame, and x_{i_norm}(n) represents an output signal at the n^{th} sampling point of the i^{th} time frame, that is, the normalized signal. μᵢ and σᵢ are the mean and variance of the input signals corresponding to the i^{th} time frame.

Next, fast autocorrelation processing is performed on the normalized signal and an autocorrelation result is output. For example, the fast autocorrelation processing may first perform a Fourier transformation on the normalized input signal by using a short-time Fourier transform (STFT) method, and perform fast autocorrelation on the Fourier transformed signal. For example, the fast autocorrelation processing procedure is shown in the following equations (2)-(4).

Xᵢ(z)=STFT(x_{i_norm}(n)) (2)

cᵢ(n)=iSTFT(Xᵢ(z)*X̅ᵢ̅(̅z̅)̅) (3)

Cᵢ=norm(cᵢ(n)) (4)

where Xᵢ(z) is a Fourier transformed signal, X̅ᵢ̅(̅z̅)̅ represents a conjugate of Xᵢ(z), iSTFT is an inverse short-time Fourier transformation, and cᵢ(n) is an autocorrelation of a signal of an i^{th} time frame. Next, a norm of cᵢ(n) is calculated to obtain Cᵢ. For example, an output Cᵢ of the final autocorrelation result is obtained based on a Euclidean norm. The output Cᵢ of the autocorrelation result represents the detection confidence, which may indicate the possibility of voice in the center channel signal.

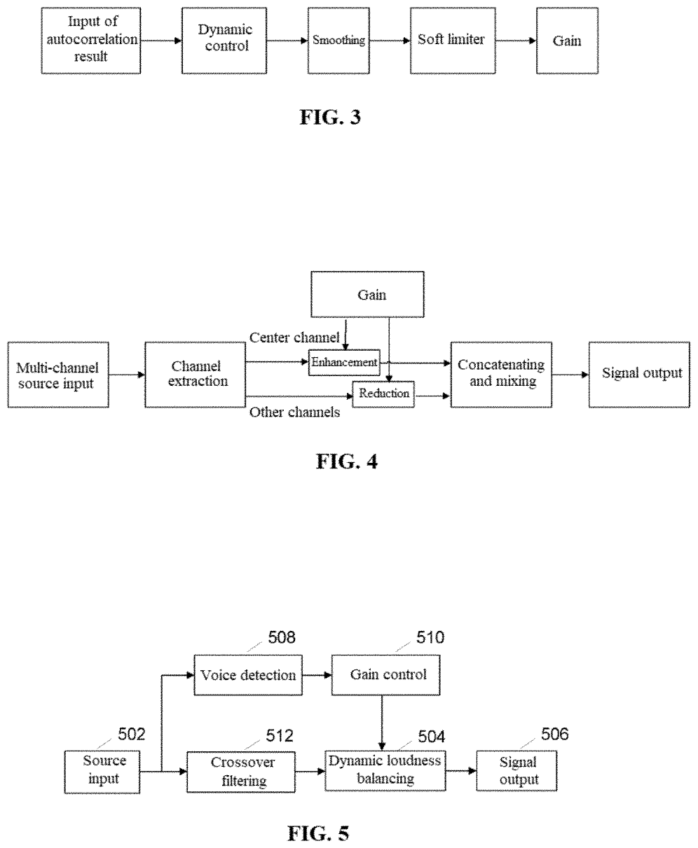

FIG. 3 exemplarily shows a schematic block diagram of a method and system of estimating a dynamic gain based on voice detection according to one or more embodiments of the present disclosure. The process of estimating a dynamic gain based on voice detection shown in FIG. 3 may be performed, for example, by the gain control module 110 in FIG. 1. For example, the detection confidence Cᵢ generated via the voice detection module 108 with reference to the process shown in FIG. 2 serves as an input to the gain control module 110. Based on the input, the gain for voice (which may also be referred to as a gain control parameter hereinafter) is output after processing in the gain control module 110 as an input to the dynamic loudness balancing module 104. In some examples, the dynamic range of the gain is calculated by the following equation (5):

Gᵢ=D₀*ln(Cᵢ+D₁) (5)

where Gᵢ represents an output of a dynamic control module; D₀ and D₁ are control parameters of a dynamic gain fluctuation range, which may be real numbers greater than zero; and ln(·) is a natural logarithmic function. In some examples, Gᵢ may be provided to dynamic loudness balancing module 104 as an output from the gain control module 110.

In some other examples, Gᵢ may be further processed and then serve as an output from the gain control module 104. For example, Gᵢ is smoothed to reduce audio distortion. In addition, a soft limiter may also be used to ensure that the gain G_{i_lim} is within a reasonable range of magnitude. For example, a tangent function of the following equation (6) may be used as the soft limiter.

G_{i_lim}=tan h(αGᵢ+β)+γ (6)

where α, β and γ are limiter parameters, which depend on the system configuration, α may be a real number greater than zero, and β and γ may be non-zero real numbers. At this moment, G_{i_lim} may serve as the output from gain control module 110.

FIG. 4 exemplarily shows a schematic diagram of a dynamic loudness balancing method of each channel according to one or more embodiments of the present disclosure. The dynamic loudness balancing processing of FIG. 4 may be performed by the dynamic loudness balancing module 104. For example, after receiving the multi-channel source input, the dynamic loudness balancing module 104 first performs channel extraction to extract a center channel signal. Then, the loudness of the center channel signal is enhanced, and the loudness of other channel signals is reduced based on the gain control parameter. Then, the enhanced center channel signal and the reduced other channel signals are concatenated and mixed to generate an output signal. The gain control parameter may be a current gain control parameter or an updated gain parameter. For example, in the case where the first path signal processing and the second path signal processing are synchronous, the gain control parameter used for the dynamic loudness balancing of a signal of a current time frame (for example, the ith time frame) is a calculated gain control parameter updated in real time, for example, Gi or G_{i_lim} updated in real time. In the case where the first path signal processing and the second path signal processing are asynchronous, since the speed of the second path signal processing including voice detection and gain estimation is relatively low, the gain control parameter used for the dynamic loudness balancing of a signal of a current time frame (for example, the ith time frame) may be the gain control parameter used for the dynamic loudness balancing of the signal of the previous time frame, such as Gᵢ₋ₙ or G_{i-n_lim}, where n is an integer greater than 0, and the value thereof may vary depending on the actual processing power of the system or the practical experience of engineers. Furthermore, based on the current/updated gain control parameter, the signal in the center channel and the signals in the other channels may be enhanced and reduced at different ratios, respectively. That is, an enhancement control parameter for enhancing the loudness of the center channel signal and an attenuation control parameter for reducing the loudness of the center channel signal may be further determined based on the current/updated gain control parameter, respectively. For example, the enhancement control parameter and the attenuation control parameter may be determined by proportional calculation, function calculation, or other calculation methods set by engineers according to system requirements or experience. As a result, the overall loudness of the system remains unchanged, but the loudness of each channel is dynamically balanced.

FIG. 5 shows a schematic diagram of a method and system according to one or more embodiments of another implementation of the present disclosure. In one or more embodiments shown in FIG. 5, the method and system of processing audio source input signals includes a source input module 502, a dynamic loudness balancing module 504, a signal output module 506, a voice detection module 508, and a gain control module 510. These modules operate on substantially the same principles as the corresponding modules 102-110 in FIG. 1. Besides, the method and system shown in FIG. 5 may further include a crossover filtering module 512. It will be understood that the difference between the method of processing described shown in FIG. 5 and the method of processing above with reference to FIGS. 1-4 is that crossover filtering is added to a first signal path. Therefore, a source input signal received from the input module 502 is processed by the crossover filtering module 512 first, and then is processed by the dynamic loudness balancing module 504 for dynamic loudness balancing. Since the frequency range of human voice is basically in a mid-frequency range, a crossover filter may be selected to process the input signal to distinguish signals in different frequency ranges. Thus, gain control is only applied to a signal in the mid frequency range in the input signal, while signals in other frequency ranges in the input signal remain unchanged. Through the added crossover filtering, it is possible to perform the dynamic loudness balancing only on the signal in the mid frequency range in the source input signal, so as to avoid distortion in a non-voice frequency range as much as possible. In order to save space, only the different parts of the embodiments shown in FIG. 5 and FIG. 1 will be described below. For other identical parts, please refer to FIGS. 1-4 and the related descriptions.

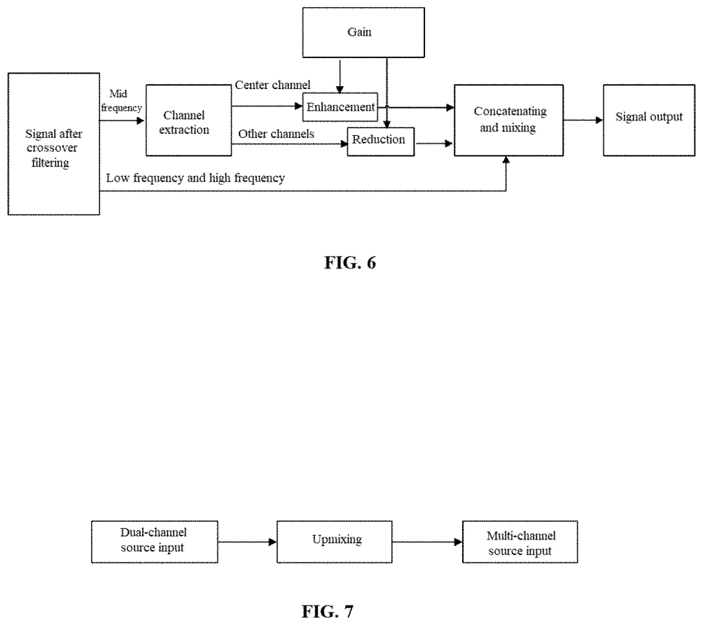

FIG. 6 shows a schematic diagram of a dynamic loudness balancing process according to one or more embodiments of the implementation in FIG. 5. As shown in FIG. 6, the source input signal after the crossover filtering may include signals in mid frequency, high frequency, and low frequency ranges. Next, dynamic loudness balancing is performed only on signals in the mid frequency range. The dynamic loudness balancing includes channel extraction to extract a center channel signal. Then, the loudness of the center channel signal is enhanced and the loudness of other channel signals is reduced based on a current/updated gain control parameter. The signals in the low frequency range and the high frequency range in the multi-channel source input signal will not be subjected to the dynamic loudness balancing, but will be directly concatenated and mixed with the signals in the mid frequency range after the dynamic loudness balancing to generate an output signal. Thus, the distortion caused by a non-voice signal may be better avoided.

A number of processing methods performed in the case where the source input is a multi-channel source input with a center channel are described above in conjunction with FIG. 1 to FIG. 6. Those skilled in the art may understand from the present disclosure that if the source input is a single-channel input, the processing methods shown in FIG. 1 to FIG. 6 may also be performed, wherein the method of center channel extraction may be omitted. That is, the signal processing of two paths described above is performed directly on the single-channel source input.

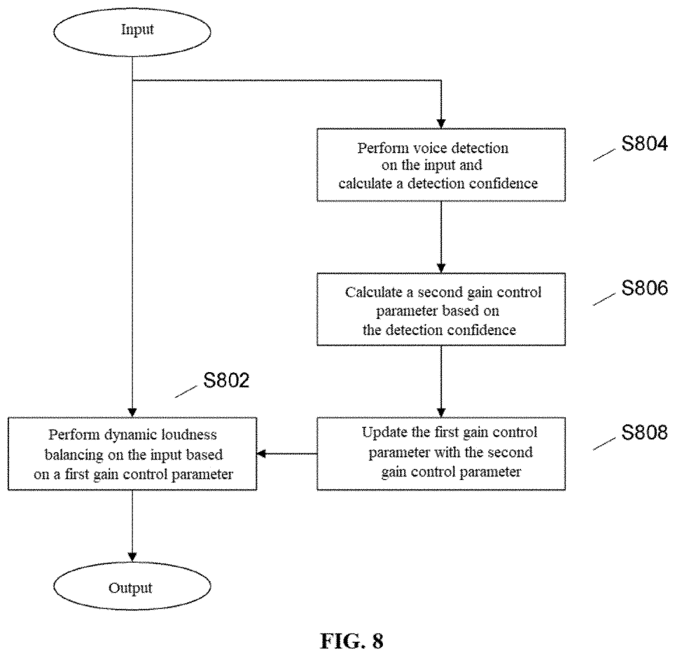

In the case where the source input is a dual-channel source input, it is necessary to add a center extraction process in advance before implementing the method and system disclosed above, so that a multi-channel source input is generated based on the dual-channel source input. FIG. 7 schematically shows a process of generating a multi-channel source input based on a dual-channel source input in the case where a source input is the dual-channel source input according to one or more embodiments of the present disclosure.

An upmixing process shown in FIG. 7 may adopt a center extraction algorithm, so as to output a multi-channel source input based on a dual-channel source input. A center extraction algorithm may, for example, include calculating a cross-correlation between left and right channel input signals, and combining the left and right channel input signals into a center channel signal, wherein the combination ratio depends on the cross-correlation, referring to the following equation (7):

center(n)=θ*corr(left(n),right(n))*(left(n)+right(n)) (7)

where left(n) is the left channel input signal, right(n) is the right channel input signal, center(n) is the center channel signal, corr( ) represents a cross-correlation function, θ is a tuning parameter in practice, and θ is greater than 0 and less than or equal to 1.

FIG. 8 schematically shows a method for dynamic voice enhancement according to one or more embodiments of the present disclosure. As shown in FIG. 8, the method includes performing a first path signal processing. The first path signal processing includes receiving an audio source input and performing dynamic loudness balancing on the audio source input based on a first gain control parameter S802. The method also includes performing a second path signal processing. The second path signal processing includes: performing voice detection on the audio source input and calculating a detection confidence S804; and calculating a second gain control parameter based on the detection confidence S806. The method may also include updating the first gain control parameter with the second gain control parameter S808, and performing the first path signal processing based on the updated first gain control parameter S802. The method shown in FIG. 8 may be performed by at least one processor.

The method and system provided by the present disclosure may be applied not only to consumer products such as Soundbars and stereo speakers, but also to products in cinema applications such as theaters and concert halls. The method and system provided by the present disclosure can better enhance the intelligibility of voice and improve the user's experience of using audio products and applications. The above-mentioned method and system described in the present disclosure with reference to the accompanying drawings may both be implemented by the at least one processor.

Aspect 1. A method for dynamic voice enhancement, comprising: performing a first path signal processing, the first path signal processing comprising receiving an audio source input and performing dynamic loudness balancing on the audio source input based on a first gain control parameter; performing a second path signal processing, the second path signal processing comprising: performing voice detection on the audio source input and calculating a detection confidence, wherein the detection confidence indicates the possibility of voice in the audio source input; and calculating a second gain control parameter based on the detection confidence; and updating the first gain control parameter with the second gain control parameter, and performing the first path signal processing based on the updated first gain control parameter.

Aspect 2. The method according to aspect 1, wherein the audio source input comprises a multi-channel source input, and the performing voice detection on the audio source input and calculating a detection confidence comprises: extracting a center channel signal from the multi-channel source input; performing normalization on the center channel signal; and performing fast autocorrelation on the normalized center channel signal, the result of the fast autocorrelation representing the detection confidence.

Aspect 3. The method according to any one of the preceding aspects, wherein calculating a second gain control parameter based on the detection confidence comprises: calculating the second gain control parameter based on a logarithmic function of the detection confidence; smoothing the calculated second gain control parameter; and limiting the smoothed second gain control parameter.

Aspect 4. The method according to any one of the preceding aspects, wherein the audio source input comprises a multi-channel source input, and performing dynamic loudness balancing on the audio source input comprises: extracting a center channel signal from the multi-channel source input; enhancing the loudness of the center channel signal and reducing the loudness of other channel signals based on the first gain control parameter or the updated first gain control parameter; and concatenating and mixing the enhanced center channel signal and the reduced other channel signals to generate an output signal.

Aspect 5. The method according to any one of the preceding aspects, further comprising: performing crossover filtering on the audio source input before performing the dynamic loudness balancing.

Aspect 6. The method according to any one of the preceding aspects, further comprising: performing the dynamic loudness balancing only on signals in a mid-frequency range of the audio source input; and concatenating and mixing signals in a low frequency range and a high frequency range of the audio source input and signals in the mid frequency range of the audio source input after the dynamic loudness balancing to generate the output signal.

Aspect 7. The method according to any one of the preceding aspects, wherein the audio source input further comprises a dual-channel source input, and the method further comprises generating a multi-channel source input based on the dual-channel source input.

Aspect 8. The method according to any one of the preceding aspects, wherein the generating a multi-channel source input based on the dual-channel source input comprises: performing a cross-correlation between a left channel signal and a right channel signal from the dual-channel source input; and generating the multi-channel source input according to a combination ratio, wherein the combination ratio depends on the result of the cross-correlation.

Aspect 9. The method according to any one of the preceding aspects, wherein the first path signal processing and the second path signal processing are synchronous or asynchronous.

Aspect 10. A system of dynamic voice enhancement, comprising: a memory configured to store computer-executable instructions; and a processor configured to execute the computer-executable instructions to implement the method according to any one of the preceding aspects 1-9.

The description of the implementations has been presented for the purposes of illustration and description. The implementations may be appropriately modified and changed according to the above description or these modifications and changes may be obtained by practicing the method. For example, unless otherwise indicated, one or more of the methods described may be performed by a suitable device and/or a combination of devices. The method may be performed by using one or more logic devices (for example, processors) in combination with one or more additional hardware elements (such as storage devices, memories, hardware network interfaces/antennas, switches, actuators, clock circuits, etc.) to perform stored instructions. The method described and associated actions may also be executed in parallel and/or simultaneously in various orders other than the order described in this application. The system described is illustrative in nature, and may include additional elements and/or omit elements. The subject matter of the present disclosure includes all novel and non-obvious combinations of the disclosed various systems and configurations as well as other features, functions, and/or properties.

The system may include additional or different logic, and may be implemented in many different ways. The processor may be implemented as a microprocessor, a microcontroller, an Application Specific Integrated Circuit (ASIC), digital signal processor DSP, discrete logic, or a combination of these and/or other types of circuits or logic. Similarly, the memory may be a dynamic random access memory (DRAM), a static random access memory (SRAM), a flash memory, or other types of memory. Parameters (for example, conditions and thresholds) and other data structures may be stored and managed separately, may be combined into a single memory or database, or may be logically and physically organized in many different ways. Programs and instruction sets may be parts of a single program, or separate programs, or distributed across a plurality of memories and processors.

As used in this application, an element or step listed in the singular form and preceded by the word “a/one” should be understood as not excluding a plurality of said elements or steps, unless such exclusion is indicated. Furthermore, references to “one implementation” or “one example” of the present disclosure are not intended to be interpreted as excluding the existence of additional implementations that also incorporate the recited features. The present invention has been described above with reference to specific implementations. However, those of ordinary skill in the art will appreciate that various modifications and changes may be made therein without departing from the broader spirit and scope of the present invention as set forth in the appended claims.

What is claimed is:

1. A method of dynamic voice enhancement, comprising:
performing a first path signal processing, the first path signal processing comprising receiving an audio source input and performing dynamic loudness balancing on the audio source input based on a first gain control parameter;
performing a second path signal processing, the second path signal processing comprising:
performing voice detection on the audio source input and calculating a detection confidence, wherein the detection confidence indicates the possibility of voice in the audio source input; and
calculating a second gain control parameter based on the detection confidence; and
updating the first gain control parameter with the second gain control parameter to provide an updated first gain control parameter, and performing the first path signal processing based on the updated first gain control parameter.

2. The method according to claim 1, wherein the audio source input comprises a multi-channel source input, and performing voice detection on the audio source input and calculating a detection confidence comprises:
extracting a center channel signal from the multi-channel source input;
performing normalization on the center channel signal; and
performing fast autocorrelation on the normalized center channel signal to provide a result representing the detection confidence.

3. The method according to claim 1, wherein the calculating a second gain control parameter based on the detection confidence comprises:
calculating the second gain control parameter based on a logarithmic function of the detection confidence;
smoothing the calculated second gain control parameter to provide a smoothed second gain control parameter; and
limiting the smoothed second gain control parameter.

4. The method according to claim 1, wherein the audio source input comprises a multi-channel source input, and the performing dynamic loudness balancing on the audio source input comprises:
extracting a center channel signal from the multi-channel source input;
enhancing a loudness of the center channel signal to provide an enhanced center channel signal and reducing a loudness of other channel signals to provide reduced other channels based on the first gain control parameter or the updated first gain control parameter; and
concatenating and mixing the enhanced center channel signal and the reduced other channel signals to generate an output signal.

5. The method according to claim 4, further comprising: performing crossover filtering on the audio source input before performing the dynamic loudness balancing.

6. The method according to claim 5, further comprising:
performing the dynamic loudness balancing only on signals in a mid frequency range of the audio source input; and
concatenating and mixing signals in a low frequency range and a high frequency range of the audio source input and signals in the mid frequency range of the audio source input after the dynamic loudness balancing to generate the output signal.

7. The method according to claim 1, wherein the audio source input further comprises a dual-channel source input, and the method further comprises generating a multi-channel source input based on the dual-channel source input.

8. The method according to claim 7, wherein the generating a multi-channel source input based on the dual-channel source input comprises:
performing a cross-correlation between a left channel signal and a right channel signal from the dual-channel source input; and
generating the multi-channel source input according to a combination ratio,
wherein the combination ratio depends on the cross-correlation.

9. The method according to claim 1, wherein the first path signal processing and the second path signal processing are synchronous or asynchronous.

10. A system of dynamic voice enhancement, comprising:
a memory configured to store computer-executable instructions; and
a processor configured to execute the computer-executable instructions to perform:
first path signal processing corresponding to receiving an audio source input and performing dynamic loudness balancing on the audio source input based on a first gain control parameter;
second path signal processing corresponding to performing voice detection on the audio source input and calculating a detection confidence, wherein the detection confidence indicates a possibility of voice in the audio source input; and
calculating a second gain control parameter based on the detection confidence; and
updating the first gain control parameter with the second gain control parameter to provide an updated first gain control parameter and performing the first path signal processing based on the updated first gain control parameter.

11. The system of claim 10, wherein the audio source input comprises a multi-channel source input, and the first path signal processing further corresponds to:
extracting a center channel signal from the multi-channel source input;
performing normalization on the center channel signal; and
performing fast autocorrelation on the normalized center channel signal to provide a result representing the detection confidence.

12. The system of claim 10, wherein the processor performs calculating a second gain control parameter based on the detection confidence by:
calculating the second gain control parameter based on a logarithmic function of the detection confidence;
smoothing the calculated second gain control parameter to provide a smoothed second gain control parameter; and
limiting the smoothed second gain control parameter.

13. The system of claim 10, wherein the audio source input comprises a multi-channel source input, and first path signal processing further corresponds to:
extracting a center channel signal from the multi-channel source input;
enhancing a loudness of the center channel signal to provide an enhanced center channel signal and reducing a loudness of other channel signals to provide reduced other channel signals based on the first gain control parameter or the updated first gain control parameter; and
concatenating and mixing the enhanced center channel signal and the reduced other channel signals to generate an output signal.

14. The system of claim 10 wherein the processor performs crossover filtering on the audio source input prior to performing the dynamic loudness balancing.

15. The system of claim 14, wherein the processor is further configured to execute the computer-executable instructions to perform:
the dynamic loudness balancing only on signals in a mid-frequency range of the audio source input; and
concatenating and mixing signals in a low frequency range and a high frequency range of the audio source input and signals in the mid frequency range of the audio source input after the dynamic loudness balancing to generate the output signal.

16. The system of claim 10, wherein the audio source input further comprises a dual-channel source input, and the processer is further configured to execute the computer-readable medium to perform generating a multi-channel source input based on the dual-channel source input.

17. The system of claim 16, wherein the processer is further configured to execute the computer-readable medium to perform generating a multi-channel source input based on the dual-channel source input by:
performing a cross-correlation between a left channel signal and a right channel signal from the dual-channel source input; and
generating the multi-channel source input according to a combination ratio,
wherein the combination ratio depends on the cross-correlation.

18. A system of dynamic voice enhancement, the system comprising:
a memory; and
a processor being operably coupled to the memory and being configured to:
perform a first path signal processing that includes receiving an audio source input and performing dynamic loudness balancing on the audio source input based on a first gain control parameter;
perform a second path signal processing that includes performing voice detection on the audio source input and calculating a detection confidence, wherein the detection confidence indicates the possibility of voice in the audio source input; and
calculate a second gain control parameter based on the detection confidence; and
update the first gain control parameter with the second gain control parameter to provide an updated first gain control parameter, and
perform the first path signal processing based on the updated first gain control parameter.

19. The system of claim 18, wherein the audio source input comprises a multi-channel source input, and the first path signal processing further comprising:
extracting a center channel signal from the multi-channel source input;
performing normalization on the center channel signal to provide a normalized center channel signal; and
performing fast autocorrelation on the normalized center channel signal to provide a result representing the detection confidence.

20. The system of claim 18, wherein the processor is configured to calculate a second gain control parameter based on the detection confidence by:
calculating the second gain control parameter based on a logarithmic function of the detection confidence to provide a calculated second gain control parameter;
smoothing the calculated second gain control parameter to provide a smoothed second gain control parameter; and
limiting the smoothed second gain control parameter.
